(19) United States
(12) Patent Application Publication
(10) Pub. No.: US 2013/0082732 A1
(43) Pub. Date: Apr. 4, 2013

(54) POWER TEST SYSTEM FOR TESTING OPERATION VOLTAGE OF POWER SUPPLY CIRCUIT OF COMPUTER

(71) Applicant: HONG-RU ZHU, Shenzhen City (CN)

(72) Inventor: HONG-RU ZHU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/479,273

(22) Filed: May 24, 2012

(30) Foreign Application Priority Data
Sep. 30, 2011 (CN) 201110293216.8

(51) Int. Cl. G01R 31/40

(52) U.S. Cl. 324/764.01

(57) ABSTRACT

A power test system is provided for testing an operation voltage of a power supply circuit of a computer. The power test system includes a reference voltage circuit, a comparator circuit, and a display circuit. The reference voltage circuit generates a pair of reference voltages. The pair of reference voltages defines a voltage range therebetween. The comparator circuit receives the pair of reference voltages and the operation voltage, compares the operation voltage with the pair of reference voltages, generates a first signal when the operation voltage is within the voltage range, and generates a second signal when the operation voltage exceeds the voltage range. The display circuit illuminates a first color light in response to the first signal, and illuminates a second color light in response to the second signal.

### BACKGROUND

1. Technical Field

The present disclosure relates to systems for testing an operation voltage of a power supply circuit of a computer.

2. Description of Related Art

Electrical devices, such as computers, are used widely all over the world. Normally, a personal computer needs a plurality of operation voltages, for example ±12V, +5V and +3V, to drive important circuits according to the advanced configuration and power interface (ACPI) specification. Before a computer is manufactured, a test may be performed to assess the performance of a power supply circuit of the computer. In a typical test, each of the operation voltages is used to drive a load circuit having a preset power rating, for detecting whether the value of each operation voltage changes and exceeds a predetermined acceptable range. For example, a 25 watt load circuit is driven by a +12V operation voltage, and the test detects whether the +12V operation voltage exceeds a range of +10.5V˜+13.5V. However, this typical test is normally performed manually using a voltage meter, and the test process is complicated.

Therefore, a new means for testing a power supply circuit is needed.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 is a block diagram of a power test system according to a first embodiment of the present disclosure, the power test system including a reference voltage circuit, a comparator circuit, and a display circuit.

FIG. 2 is a diagram of the reference voltage circuit of FIG. 1 according to one embodiment of the present disclosure.

FIG. 3 is a diagram of the comparator circuit and the display circuit of FIG. 1 according to one embodiment of the present disclosure.

FIG. 4 is a block diagram of a power test system according to a second embodiment of the present disclosure, the power test system including a voltage inverting circuit.

FIG. 5 is a diagram of the voltage inverting circuit of FIG. 4 according to one embodiment of the present disclosure.

### DETAILED DESCRIPTION

Reference will now be made to the drawings to describe various embodiments in detail.

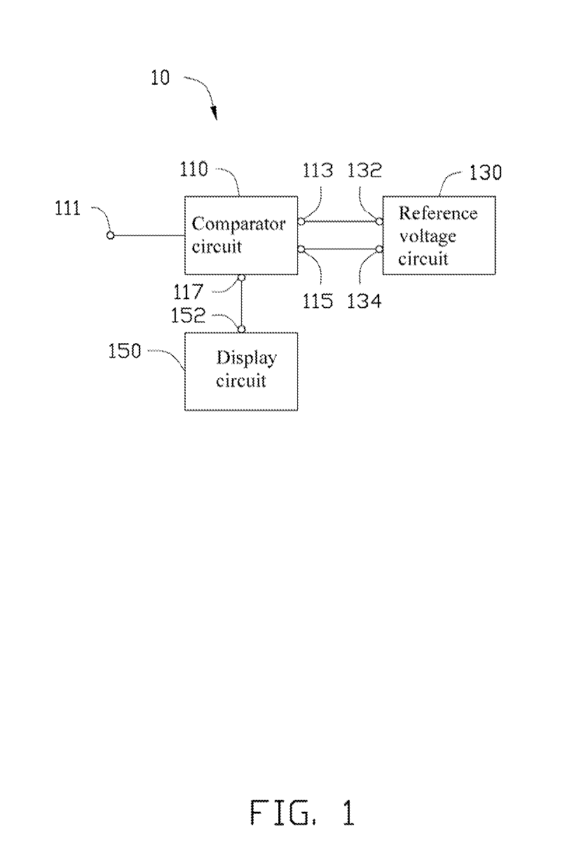

FIG. 1 is a block diagram of a power test system 10 according to a first embodiment of the present disclosure. The power test system 10 includes a comparator circuit 110, a reference voltage circuit 130, and a display circuit 150.

The reference voltage circuit 130 includes a first reference output 132 and a second reference output 134. The reference voltage circuit 130 generates a first reference voltage and a second reference voltage. The first reference voltage and the second reference voltage are output from the first reference output 132 and second reference output 134, respectively. In this embodiment, the first and the second reference voltages are defined as a pair of reference voltages, and are generated in response to a value and a power rating of an operation voltage to be tested. In one embodiment, the reference voltage circuit 130 stores predetermined parameters, such as a value and a power rating, of a plurality of operation voltages, and generates a pair of reference voltages in response to the parameters of each operation voltage. In alternative embodiments, the reference voltage circuit 130 may include a switch, for controlling the reference voltage circuit 130 to generate different pairs of reference voltages in response to different operation voltages. In one embodiment, the operation voltage is provided from an external power supply circuit of the computer. In one embodiment, the operation voltage to be tested is greater than the second reference voltage and smaller than the first reference voltage.

The comparator circuit 110 includes a test voltage input 111 receiving the operation voltage to be tested, a first input 113 receiving the first reference voltage from first reference output 132, a second input 115 receiving the second reference voltage from the second reference output 134, and a display control terminal 117. The comparator circuit 110 compares the received operation voltage with the first and the second reference voltages, and determines if the operation voltage is within the range between the first and the second reference voltages. The comparator circuit 110 generates a first signal when the operation voltage is within the range. The comparator circuit 110 generates a second signal when the operation voltage is out of the range. The first and the second signals are output from the display control terminal 117 to the display circuit 150.

The display circuit 150 includes an enable input 152 receiving the first and the second signals. When the display circuit 150 receives the first signal, the display circuit 150 displays first information to indicate that the operation voltage complies with a voltage standard. When the display circuit 150 receives the second signal, the display circuit 150 displays second information to indicate that the operation voltage does not comply with the voltage standard.

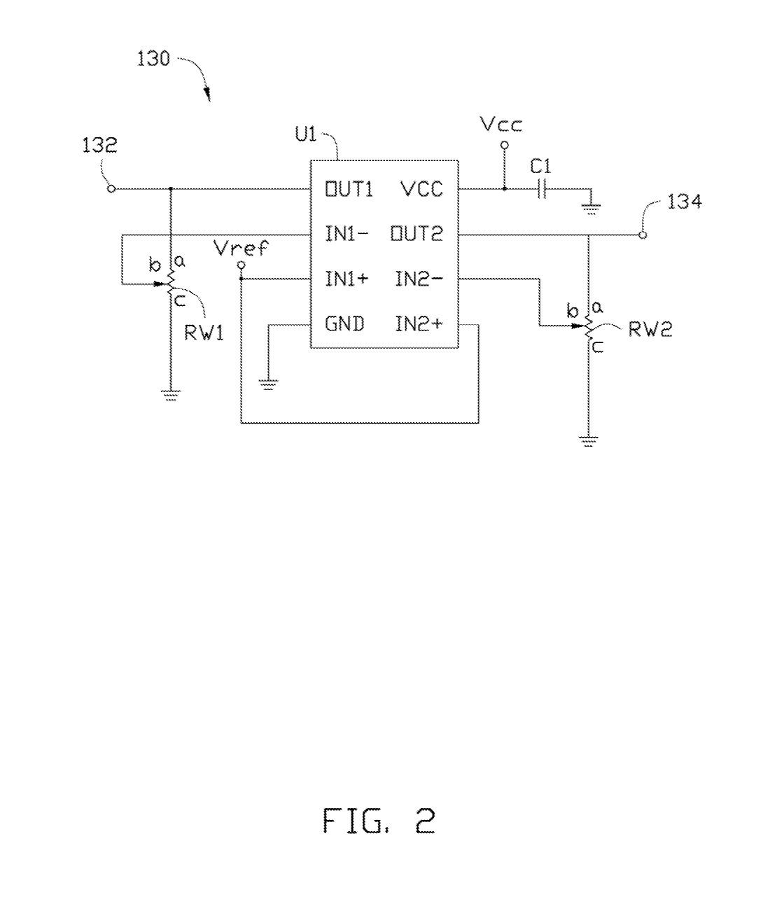

FIG. 2 is a diagram of the reference voltage circuit 130 according to one embodiment of the present disclosure. The reference voltage circuit 130 includes a first chip U1, a first adjustable resistor RW1, a second adjustable resistor RW2, and a first capacitor C1. Each adjustable resistor RW1, RW2 includes a first terminal “a,” an adjusting terminal “b,” and a second terminal “c.”

The first chip U1 includes a power pin VCC, a ground terminal GND (such as a ground pin), a first noninverting input IN1+, a first inverting input IN1−, a first output OUT1, a second noninverting input IN2+, a second inverting input IN2−, and a second output OUT2. In one embodiment, the first chip U1 further includes two integrated comparators (not shown) therein.

More particularly, the following connections exist in the first chip U1. The power pin VCC is grounded via the first capacitor C1, and receives a first driving voltage Vcc. The first noninverting input IN1+ and the second noninverting input IN2+ receive a standard reference voltage Vref corresponding to the operation voltage to be tested.

The first output OUT1 is defined as the first reference output 132, and is grounded via the first terminal “a” and the second terminal “c” of the first adjustable resistor RW1. The first inverting input IN1− is connected to the adjusting terminal “b” of the first adjustable resistor RW1. The second output OUT2 is defined as the second reference output 134, and is grounded via the first terminal “a” and the second terminal “c” of the second adjustable resistor RW2. The second inverting input IN2− is connected to the adjusting terminal “b” of the second adjustable resistor RW2.

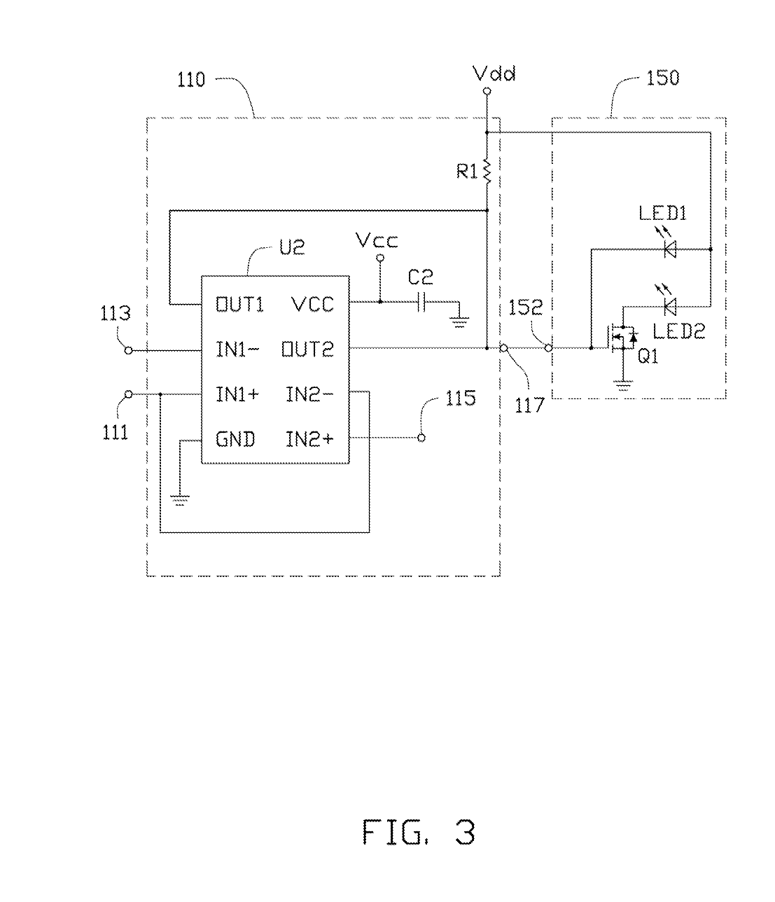

FIG. 3 is a diagram of the comparator circuit 110 and the display circuit 150 according to one embodiment of the present disclosure.

The display circuit 150 includes a first color light emitting diode LED1, a second color light emitting diode LED2, and a transistor Q1. In one embodiment, the first color light emitting diode LED1 and the second color light emitting diode LED2 are a green light emitting diode and a red light emitting diode, respectively. The transistor Q1 is an n-channel metal-oxide-semiconductor field effect transistor (NMOSFET).

The comparator circuit 110 includes a second chip U2 that is the same as the first chip U1, a second capacitor C2, and a first resistor R1. The second chip U2 includes a power pin VCC, a ground terminal GND (such as a ground pin), a first noninverting input IN1+, a first inverting input IN1−, a first output OUT1, a second noninverting input IN2+, a second inverting input IN2−, and a second output OUT2. In one embodiment, the second chip U2 further includes two integrated comparators (not shown) therein.

More particularly, the following connections exist in the second chip U2. The power pin VCC is grounded via the second capacitor C2, and receives the first driving voltage Vcc. The first noninverting input IN1+ is connected to the second inverting input IN2−, and is defined as the test voltage input 111. The first inverting input IN1− is defined as the first input 113. The second noninverting input IN2+ is defined as the second input 115. The first output OUT1 is connected to a second driving voltage Vdd via the first resistor R1. The second output OUT2 is connected to the first output OUT1, and is defined as the display control terminal 117. The second driving voltage Vdd is connected to the second output OUT2 via the forward biased first color light emitting diode LED1. The second driving voltage Vdd is grounded via the forward biased second color light emitting diode LED2 and the transistor Q1 in series. A gate of the transistor Q1 is connected to the second output OUT2.

In operation of the power test system 10, an operation voltage to be tested is selected by a user and is provided to the test voltage input 111. The reference voltage circuit 130 generates a pair of reference voltages, namely the first and the second reference voltages, in response to a standard reference voltage Vref. The standard reference voltage Vref corresponds to or is substantially equal to the operation voltage to be tested. In this example, the first and second reference voltages are designated as V1 and V2, respectively. The comparator circuit 110 receives the operation voltage to be tested and the first and second reference voltages V1 and V2. In this embodiment, the values of the first and second reference voltages V1 and V2 may be adjusted by controlling the first and second adjustable resistors RW1 and RW2, respectively.

In a first condition that the operation voltage is within the range defined by the first and second reference voltages V1 and V2, the comparator circuit 110 generates a low voltage, for example 0 volts, as the first signal. Under this condition, the transistor Q1 is turned off and only the first color light emitting diode LED1 is lit up by the second driving voltage Vdd to illuminate the first color light. The first color light indicates that the operation voltage complies with the voltage standard. In a second condition that the operation voltage is out of the range defined by the first and second reference voltages V1 and V2, the comparator circuit 110 generates a high voltage, for example 5 volts, as the second signal. Under this condition, the transistor Q1 is turned on and only the second color light emitting diode LED2 is lit up by the second driving voltage Vdd to illuminate the second color light. The second color light indicates that the operation voltage does not comply with the voltage standard.

In one embodiment, the values of the first and second reference voltages V1 and V2 may be adjusted by controlling the first and second adjustable resistors RW1 and RW2, respectively. In one embodiment, the operation voltage to be tested has a predetermined value and power rating, for example 12 volts and 25 watts. The first and second reference voltages V1 and V2 are 14 volts and 12 volts, respectively. The first and second color light emitting diodes LED1 and LED2 are green and red light emitting diodes, respectively.

The power test system 10 is convenient for the user to test the operation voltage, since the user can simply determine whether the operation voltage complies with the voltage standard by observing the different color lights that are shown.

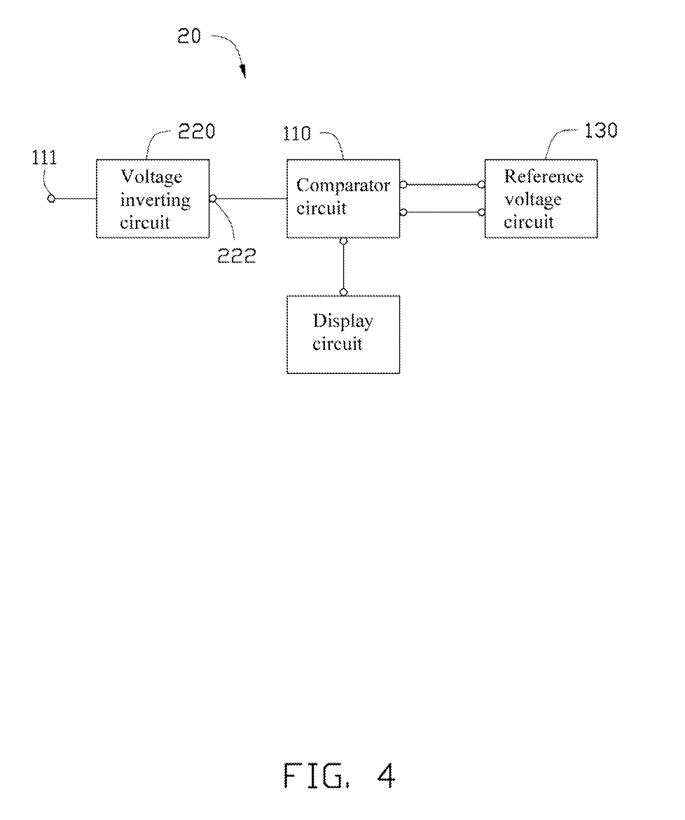

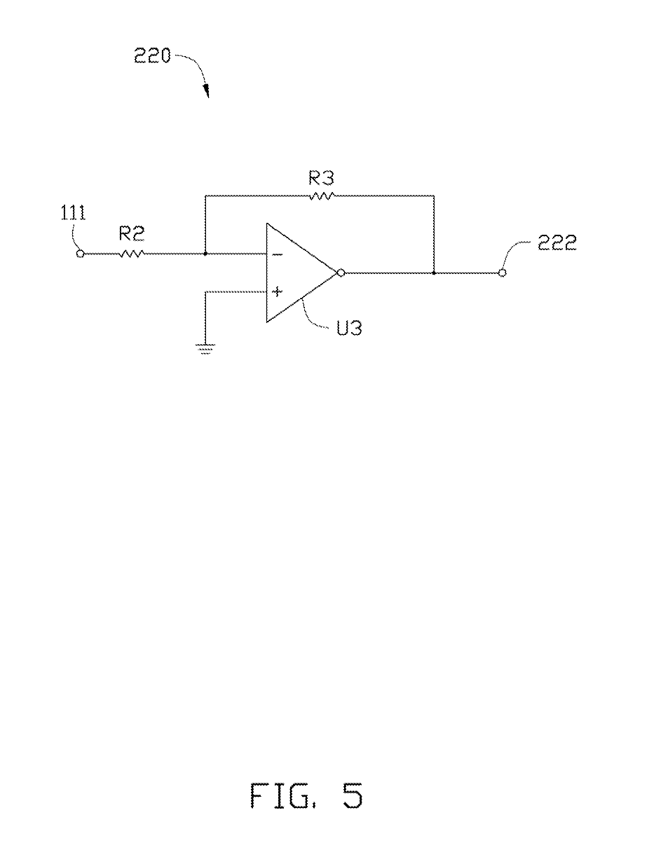

FIGS. 4 and 5 show aspects of a power test system 20 according to a second embodiment of the present disclosure. The power test system 20 differs from the power test system 10 of the first embodiment in that the power test system 20 further includes a voltage inverting circuit 220. The voltage inverting circuit 220 receives and processes the operation voltage to be tested, and outputs an attenuated and inverted operation voltage to the comparator circuit 110. In this embodiment, the voltage inverting circuit 220 includes a comparator U3, a second resistor R2, a third resistor R3, and an output 222. An inverting input of the comparator U3 is connected to the test voltage input 111 via the second resistor R2, a noninverting input of the comparator U3 is grounded, and an output of the comparator U3 is connected to the output 222. In addition, the test voltage input 111 is connected to the output 222 via the second resistor R2 and the third resistor R3 in series. The output 222 is connected to the first noninverting input IN1+ of the comparator circuit 110. In other respects, the structure and operation of the power test system 20 are substantially the same as those of the power test system 10 of the first embodiment.

It is to be understood that even though numerous characteristics and advantages of the present embodiments have been set forth in the foregoing description, together with details of the structures and functions of the embodiments, the disclosure is illustrative only; and that changes may be in detail, especially in matters of arrangement of parts, within the principles of the embodiments, to the full extent indicated by the broad general meaning of the terms in which the appended claims are expressed.

What is claimed is:

1. A power test system for testing an operation voltage of a power supply circuit of a computer, the power test system comprising:
a reference voltage circuit configured to generate a pair of reference voltages, the pair of reference voltages defining a voltage range therebetween;
a comparator circuit configured to receive the pair of reference voltages and also the operation voltage, compare the operation voltage with the pair of reference voltages, generate a first signal when the operation voltage is within the voltage range, and generate a second signal when the operation voltage exceeds the voltage range; and
a display circuit configured to illuminate a first color light in response to the first signal and illuminate a second color light in response to the second signal.

2. The power test system of claim 1, wherein the pair of reference voltages is defined as a first reference voltage and a second reference voltage, and the first reference voltage is greater than the second reference voltage.

3. The power test system of claim 1, wherein the pair of reference voltages is generated according to a value and a power rating of the operation voltage.

4. The power test system of claim 1, wherein the reference voltage circuit is further configured to receive a standard reference voltage corresponding to the operation voltage, and generate the pair of reference voltages according to the standard reference voltage.

5. The power test system of claim 1, wherein the first and the second color lights are green and red lights, respectively.

6. The power test system of claim 1, wherein illumination of the first color light indicates that the operation voltage complies with a predetermined voltage standard corresponding to the voltage range.

7. The power test system of claim 6, wherein illumination of the second color light indicates that the operation voltage does not comply with the predetermined voltage standard.

8. The power test system of claim 6, wherein the reference voltage circuit comprises a switch configured to control the reference voltage circuit to generate different pairs of reference voltages in response to different operation voltages to be tested.

9. The power test system of claim 1, wherein the reference voltage circuit comprises a first chip, a first adjustable resistor, a second adjustable resistor, and a first capacitor, the first chip comprises a power pin, a ground terminal, a first noninverting input, a first inverting input, a first output, a second noninverting input, a second inverting input, and a second output, and:
the power pin is grounded via the first capacitor and is configured to receive a first driving voltage;
the first noninverting input and the second noninverting input are configured to receive a standard reference voltage;
the first output is configured to output one of the pair of reference voltages;
the second output is configured to output the other one of the pair of reference voltages;
the first inverting input is connected to an adjusting terminal of the first adjustable resistor; and
the second inverting input is connected to an adjusting terminal of the second adjustable resistor.

10. The power test system of claim 9, wherein the first output is grounded via the first adjustable resistor, the second output is grounded via the second adjustable resistor, and the first and the second adjustable resistors are operable to adjust values of the pair of reference voltages, correspondingly.

11. The power test system of claim 9, wherein the comparator circuit comprises a second chip, a second capacitor, and a resistor, the second chip comprises a power pin, a ground terminal, a first noninverting input, a first inverting input, a first output, a second noninverting input, a second inverting input, a second output, and:
the power pin of the second chip is grounded via the second capacitor and is configured to receive the first driving voltage;
the first noninverting input of the second chip is connected to the second inverting input of the second chip and is configured to receive the operation voltage;
the first inverting input of the second chip is configured to receive one of the pair reference voltages;
the second noninverting input of the second chip is configured to receive the other one of the pair reference voltages;
the first output of the second chip is configured to receive a second driving voltage via the resistor; and
the second output of the second chip is connected to the first output of the second chip and is configured to output the first signal and the second signal.

12. The power test system of claim 11, wherein the display circuit comprises a first color light emitting diode, a second color light emitting diode, and a transistor, the second driving voltage is provided to the second output of the second chip via the forward biased first color light emitting diode, the second driving voltage is grounded via the forward biased second color light emitting diode and the transistor in series, and a gate of the transistor is connected to the second output of the second chip.

13. The power test system of claim 1, further comprising a voltage inverting circuit structured and arranged to receive the operation voltage, process the operation voltage, and output an attenuated and inverted operation voltage to the comparator circuit as the operation voltage that the comparator circuit is configured to receive.

14. The power test system of claim 13, wherein the voltage inverting circuit comprises a comparator, an inverting input of the comparator is provided to receive the operation voltage, a noninverting input of the comparator is grounded, and an output of the comparator is provided to output the attenuated and inverted operation voltage to the comparator circuit.

15. A power test system for testing an operation voltage provided by a power supply circuit of a computer, the power test system comprising:
a reference voltage circuit generating a first reference voltage and a second reference voltage, the first reference voltage and the second reference voltage defining a voltage range therebetween;
a comparator circuit receiving the first reference voltage and the second reference voltage and also the operation voltage, comparing the operation voltage with the first and second reference voltages, generating a first signal when the operation voltage is within the voltage range, and generating a second signal when the operation voltage exceeds the voltage range; and
a display circuit illuminating a first color light in response to the first signal and illuminating a second color light in response to the second signal.

16. The power test system of claim 15, wherein the first reference voltage is greater than the second reference voltage.

17. The power test system of claim 15, wherein the first reference voltage and the second reference voltage are generated according to a value and a power rating of the operation voltage.

18. The power test system of claim 15, wherein the reference voltage circuit further receives a standard reference voltage corresponding to the operation voltage to be tested, and the first reference voltage and the second reference voltage are generated according to the standard reference voltage.

19. The power test system of claim 15, wherein the first and the second first color lights are green and red color lights, respectively.

20. The power test system of claim 15, wherein the first color light indicates the operation voltage complies with a voltage standard, and the second color light indicates the operation voltage does not complies with the voltage standard.
